(19) United States
(12) Patent Application Publication
(10) Pub. No.: US 2026/0068042 A1
(43) Pub. Date: Mar. 5, 2026

(54) CERAMIC CIRCUIT BOARD, MANUFACTURING METHOD FOR CERAMIC CIRCUIT BOARD, AND BRAZING MATERIAL FOR CIRCUIT FORMATION

(71) Applicant: PROTERIAL, LTD., Tokyo (JP)

(72) Inventors: Shun TAKANO, Tokyo (JP); Takashi Nogawa, Tokyo (JP)

(73) Assignee: PROTERIAL, LTD., Tokyo (JP)

(21) Appl. No.: 19/287,388

(22) Filed: Jul. 31, 2025

(30) Foreign Application Priority Data
Sep. 2, 2024 (JP) 2024-150607
Jul. 24, 2025 (JP) 2025-123850

(51) Int. Cl. H05K 1/03; H05K 1/09; H05K 1/11; H05K 3/12

(52) U.S. Cl. CPC H05K 1/0306; H05K 1/092; H05K 1/115; H05K 3/1291; H05K 2201/0215; H05K 2201/0266

(57) ABSTRACT

A low-cost ceramic circuit board that offers enhanced design flexibility in circuit layer thickness by increasing the bonding strength between a circuit layer and a ceramic substrate. A ceramic circuit board includes a ceramic substrate and a metal circuit layer formed on the ceramic substrate. The metal circuit layer contains Cu, Mg, at least one element selected from the group including Sn, Sb, and Bi, and at least one active metal element selected from Ti, Zr, Hf, V, Nb, Ta, Cr, Mo, and W.

### TECHNICAL FIELD

This disclosure relates to a ceramic circuit board, a manufacturing method for a ceramic circuit board, and a brazing material for circuit formation.

### BACKGROUND ART

Ceramic circuit boards in which a metal paste is applied to the surface of a ceramic substrate and sintered to form metal circuit are known. It is preferable that such ceramic circuit boards have high thermal conductivity and excellent heat dissipation.

For example, Patent Literature 1 discloses a manufacturing method for a metallized substrate, the method comprising a process for manufacturing a first laminate by laminating a first paste layer containing copper powder and titanium hydride powder on a sintered nitride ceramic substrate, a process for manufacturing a second laminate by laminating a second paste layer containing alloy powder of silver and copper on the first paste layer of the first laminate, and a process for firing the second laminate to form a titanium nitride layer and a metal layer on the sintered nitride ceramic substrate.

Patent Literature 2 discloses a manufacturing method for a metallized substrate, the method comprising an adhesion process for causing a conductive composition including Ag particles, metallic components, and glass particles to adhere to a ceramic substrate, and a firing process for forming a conductive part by firing the conductive composition adhered to the ceramic substrate.

### CITATION LIST

### Patent Literature

[Patent Literature 1] Japanese Patent No. 5731476 Gazette

[Patent Literature 2] Japanese Patent No. 7523948 Gazette

### SUMMARY OF INVENTION

### Technical Problem

As stated in Patent Literature 1, when a paste (brazing material) containing silver (Ag) as the main component is used, the manufacturing cost for a ceramic circuit board is relatively high. In addition, there are multiple paste layers which are laminated in Patent Literature 1, so the process cost is also relatively high.

Moreover, when the ceramic substrate is an oxide such as alumina (Al₂O₃), it is necessary to form a layer of molybdenum (Mo) or the like on the surface of the ceramic substrate in advance to ensure adhesion between the ceramic substrate and the metal layer, which leads to increased manufacturing costs.

Furthermore, as described in Patent Literature 2 for example, when a circuit layer is formed using a conductive paste containing conductive particles such as Ag or copper (Cu) and glass particles (glass frit), it is difficult to form a thick layer of circuit for enhancing heat dissipation and conductivity because sufficient bonding strength with the ceramic substrate cannot be obtained.

The purpose of this disclosure is to provide a ceramic circuit board that offers enhanced design flexibility in circuit layer thickness by increasing the bonding strength between a circuit layer and a ceramic substrate with suppressing cost.

### Solution to Problem

According to one aspect of this disclosure, provided is
a ceramic circuit board comprising
a ceramic substrate, and
a metal circuit layer formed on the ceramic substrate, wherein
the metal circuit layer contains
Cu,
Mg,
at least one element selected from the group consisting of Sn, Sb, and Bi, and
at least one active metal element selected from the group consisting of Ti, Zr, Hf, V,

Nb, Ta, Cr, Mo, and W.

According to another aspect of this disclosure, provided is
a method for manufacturing a ceramic circuit board, the method comprising:
   placing a brazing material for circuit formation on a ceramic substrate in such a manner that the brazing material for circuit formation corresponds to a circuit pattern, the brazing material for circuit formation containing
   Cu,
   Mg,
   at least one first element selected from the group consisting of Sn, Sb, and Bi, and
at least one active metal element selected from the group consisting of Ti, Zr, Hf, V, Nb, Ta, Cr, Mo, and W; and
heating and holding the ceramic substrate on which the brazing material for circuit formation has been placed.

According to another aspect of this disclosure, provided is
a brazing material for circuit formation comprising:
Cu;
Mg;
at least one first element selected from the group consisting of Sn, Sb, and Bi; and
at least one active metal element selected from the group consisting of Ti, Zr, Hf, V, Nb, Ta, Cr, Mo, and W.

### Advantageous Effects of Invention

According to this disclosure, it is possible to provide a ceramic circuit board that offers enhanced design flexibility in circuit layer thickness by increasing the bonding strength between a circuit layer and a ceramic substrate with suppressing cost.

### BRIEF DESCRIPTION OF DRAWINGS

FIG. 1 is a schematic cross-sectional view of a ceramic circuit board 100 in an embodiment of this disclosure.

FIG. 2 is a schematic view explaining a manufacturing method for the ceramic circuit board 100 in the embodiment of this disclosure.

FIG. 3 is a schematic cross-sectional view of the ceramic circuit board 100 in another embodiment of this disclosure.

FIG. 4 is an exterior image of sample 5 in the examples of this disclosure.

FIG. 5 is a cross-sectional SEM image of sample 5 in the examples of this disclosure.

### DESCRIPTION OF EMBODIMENTS

### Embodiments of this Disclosure

An embodiment of this disclosure is explained below, referring to the aforementioned drawings. All of the drawings used in the following explanations are schematic. The dimensions and proportions of each element shown in the drawing may not necessarily correspond to reality. Also, the dimensions and proportions of each element may not necessarily be consistent between the drawings. In this description, “A to B” means the numerical range of “A or more and B or less.”

### (1) Brazing Material for Circuit Formation

First, a brazing material for manufacturing the ceramic circuit board for this embodiment is explained. The brazing material for circuit formation for this embodiment is a Cu—Mg based active metal brazing material containing Cu as the main component (for example, the content of Cu is 40 at % or more, or Cu is the element having the highest content among the elements contained in the brazing material). Specifically, the brazing material for circuit formation includes copper (Cu), magnesium (Mg), at least one first element (hereinafter also referred to as “evaporation suppression element”) selected from the group consisting of tin (Sn), antimony (Sb), and bismuth (Bi), and at least one active metal element selected from the group consisting of titanium (Ti), zirconium (Zr), hafnium (Hf), vanadium (V), niobium (Nb), tantalum (Ta), chromium (Cr), molybdenum (Mo), and tungsten (W). The brazing material for circuit formation may additionally contain at least one second element (hereinafter also referred to as “melting point-lowering element”) selected from the group consisting of Ag, In, and Mn. The brazing material for circuit formation for this embodiment preferably contains Mg, an evaporation suppression element for Mg, an active metal element, and inevitable impurities, with the balance of Cu, and may also contain a melting point-lowering element.

Cu is an element that forms a solid solution that mainly forms the metal circuit layer when the brazing material for circuit formation is heated and bonded onto the ceramic substrate. Cu also contributes to the ductility and malleability of the metal circuit layer.

Mg acts to lower the melting point of Cu alloy and lower the bonding temperature of the brazing material for circuit formation. Mg also acts to enhance the wettability of the brazing material for circuit formation to the ceramic substrate.

The evaporation suppression element for Mg is an element that is able to react easily with Mg when the brazing material for circuit formation is heated, and acts to form a compound with Mg as a result of reacting with Mg. This compound has a higher melting point than Mg, and is formed as an eutectic that melts at the bonding temperature, while the molten components such as Mg are less likely to evaporate. Therefore, the evaporation suppression element for Mg is able to react with Mg at the time of bonding to suppress evaporation of Mg. For example, the evaporation suppression element for Mg acts to form a ternary intermetallic compound with Cu and Mg when the brazing material for circuit formation is heated, and improve the strength of the intermetallic compound. As the evaporation suppression element for Mg, at least one element selected from the group consisting of Sn, Sb, and Bi may be used.

The melting point-lowering element acts to lower the melting point of the brazing material for circuit formation. The melting point-lowering element also contributes to improvement of wettability of the brazing material for circuit formation. As the melting point-lowering element, at least one element selected from the group consisting of Ag, In, and Mn may be used. The melting point-lowering element is either dissolved in Cu or diffused in the bonded material. Ag may be present as a single phase in the metal circuit layer. It is preferable that the content of the melting point-lowering element selected from the group consisting of Ag, In and Mn is less than the content of Cu of the brazing material for circuit formation in light of suppressing cost.

The active metal element acts to react with the ceramic substrate to form a compound (for example, a nitride) when the brazing material for circuit formation is heated, and increase the bonding strength between the ceramic substrate and the metal circuit layer. As the active metal element, at least one element selected from the group consisting of Ti, Zr, Hf, V, Nb, Ta, Cr, Mo, and W may be used. In particular, it is preferable to use Ti.

As for the content of each metal element constituting the brazing material for circuit formation, for example, the content of Cu is preferably 40 to 85 at % (40 at % or more, and 85 at % or less), the content of Mg is preferably 1 to 25 at % (1 at % or more, and 25 at % or less), the total content of the evaporation suppression element for Mg is preferably 1 to 25 at % (1 at % or more, and 25 at % or less), and the total content of the active metal element is preferably 0.1 to 10 at % (0.1 at% or more, and 10 at % or less). In addition, the total content of the melting point-lowering element is preferably 50 at % or less (less than 40 at % for each element alone). The total content of the melting point-lowering element is more preferably 35at % or less, and even more preferably 20 at % or less.

Provided that the content of Mg is X at % and the content of the evaporation suppression element for Mg is Y at %, the relationship X−5≤Y≤X+5 is preferably satisfied. As a result of including each element in such a content, it is possible to achieve a prescribed bonding strength in the metal circuit layer while lowering the bonding temperature of the brazing material for circuit formation. Y is greater than 0 and does not exceed 100.

An embodiment of the brazing material for circuit formation is not specifically limited, but the brazing material for circuit formation is preferably a paste or powder from the viewpoint of homogeneously obtaining a phase structure (described later) in the metal circuit layer. The brazing material paste is formed from powder containing the aforementioned elements, a solvent, a binder, etc.

The form of inclusion (addition) of the elements in the brazing material for circuit formation is not specifically limited, and the elements may be included as powder formed from each element or as a compound powder containing some of the elements. The form of inclusion of the elements is described below.

Mg may be contained in the brazing material in the form of powder containing at least one of, for example, Mg alone, a solid solution of Mg and other elements, a compound of Mg with Cu (MgCu₂), a compound of Mg with the active metal element, a compound of Mg with the evaporation suppression element for Mg, or a compound of Mg with the melting point-lowering element (powder may be added to the brazing material). In this case, at least a portion of Mg is preferably contained in brazing material in the form of powder containing an intermetallic compound with the evaporation suppression element for Mg. A preferable example of the form of inclusion of Mg is alloy powder formed from an intermetallic compound containing Mg and an evaporation suppression element for Mg and Mg, or alloy powder formed from an intermetallic compound containing Mg and an evaporation suppression element for Mg and an evaporation suppression element for Mg. Alternatively, Mg may be contained in the form in which the aforementioned alloy powder is mixed with at least one from among Mg powder, Mg—Cu intermetallic compound powder, and the like. As a result of making at least a portion of Mg in the form of an intermetallic compound with an evaporation suppression element for Mg in advance, it is possible to suppress evaporation of Mg during the melting of the brazing material for circuit formation more reliably. The alloy powder is not a mixture of powder containing one element and powder containing another element, but powder containing each element in the form of an alloy in a single particle. The solid solution containing other elements is a solid solution in which some of the elements forming the solid solution in the crystal have been substituted by other elements, or a solid solution in which other elements have infiltrated into the gap in the crystal lattice.

The alloy powder may contain at least Mg and an evaporation suppression element for Mg and may also contain Cu. When the evaporation suppression element for Mg is Sn, Mg₂Sn or Cu₄MgSn can be used for the alloy powder. When the evaporation suppression element for Mg is Sb, Mg₃Sb₂, CuMgSb, or the like can be used. When the evaporation suppression element for Mg is Bi, Mg₃Bi₂, CuMgBi, or the like can be used.

The alloy powder may be prepared by mixing and melting Mg, the evaporation suppression element for Mg, and, if necessary, Cu and the melting point-lowering element, and then atomizing the mixture to obtain powder containing each of the elements.

The content (addition amount) of the alloy powder containing Mg and the evaporation suppression element for Mg is not particularly limited, but it is preferable that the content of Mg derived from the alloy powder is 40% or more of the total Mg content in the brazing material for circuit formation. For example, when the alloy powder containing Mg and the evaporation suppression element for Mg is used together with at least one from among metal powder formed from Mg alone, Mg-active metal alloy powder, Mg—Cu intermetallic compound powder, and the like, it is preferable to set the content of the alloy powder containing Mg and the evaporation suppression element for Mg such that the content of Mg derived from the alloy powder containing Mg and the evaporation suppression element for Mg is 40% or more of the total content in the brazing material for circuit formation. The alloy powder content may be 100% of the total Mg content in the brazing material for circuit formation, that is, the brazing material for circuit formation may contain only the alloy powder. As a result of adopting such a content, it is possible to suppress evaporation of Mg more stably.

Cu may be contained in the brazing material in the form of powder containing at least one of, for example, Cu alone, a Cu solid solution containing other elements, an intermetallic compound with Mg (for example, MgCu₂), an intermetallic compound with an evaporation suppression element for Mg or melting point-lowering element (for example, Cu₃Sn, Cu₃Sb), an intermetallic compound with an active metal element (for example, Cu—Ti compound (Cu₄Ti or Cu₃Ti₂)), or an alloy formed from Cu alone, a solid solution, and an intermetallic compound formed with Cu.

The evaporation suppression element for Mg may be contained in the brazing material in the form of powder containing at least from among, for example, the evaporation suppression element for Mg alone, a solid solution containing other elements, a compound formed with at least one from among Mg, Cu, a melting point-lowering element, and an active metal element, and an alloy formed from the evaporation suppression element for Mg alone, a solid solution, and an intermetallic compound formed with Cu.

The melting point-lowering element may be contained in the brazing material in the form of powder containing at least one from among, for example, the melting point-lowering element alone, a solid solution containing other elements, a hydride, and an intermetallic compound formed with at least one element from among Mg, Cu, an evaporation suppression element for Mg, and an active metal element.

The active metal element may be contained in the brazing material in the form of powder containing at least one from among, for example, the active metal element alone, a solid solution containing other elements, and an intermetallic compound formed with at least one element from among Mg, Cu, an evaporation suppression element for Mg, and a melting point-lowering element.

In the brazing material for circuit formation, the particle size of powder containing Cu, Mg, an evaporation suppression element for Mg, a melting point-lowering element, and an active metal element can be changed according to the thickness of the metal circuit layer, for example. Specifically, the particle size is preferably 150 μm or less in the median diameter D50. Meanwhile, although the lower limit of the median diameter D50 is not particularly limited, it is preferable to adopt a median diameter D50 of 1 μm or more from the viewpoint of suppressing the effect of surface oxidation of the powder. The median diameter D50 is measured using a laser diffraction particle size distribution measurement device, for example, and shows a particle size of 50% in the volume-based integrated distribution curve.

In the brazing material for circuit formation, metal powder can be used as a paste if necessary, and in addition to the metal powder, a binder, a solvent, a surfactant, a plasticizer, a dispersant, etc. may also be included. As the binder, polyvinyl alcohol, ethyl cellulose, polymethacrylic acid, polyacrylic acid, etc. can be used, for example. As the solvent, alcohol such as terpineol or butanediol, or toluene can be used, for example. As the surfactant, a cationic, anionic, or nonionic active agent can be used, for example.

The method for preparing the brazing material for circuit formation is not particularly limited, and any conventionally known method may be used. In addition, the brazing material for circuit formation in this embodiment is used as a conductive material for forming a conductive layer and a conductive pattern on the substrate.

### (2) Configuration of Ceramic Circuit Board

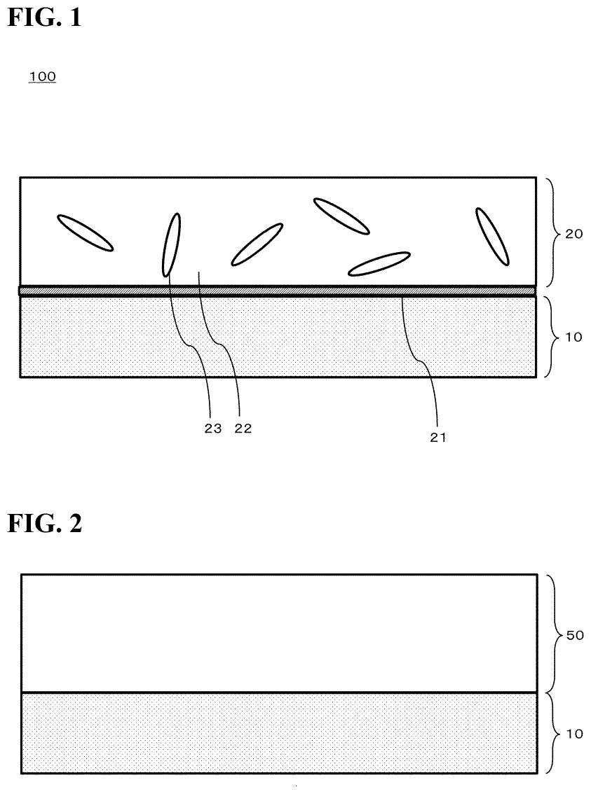

Next, the configuration of the ceramic circuit board 100 for this embodiment is explained. FIG. 1 is a schematic cross-sectional view of the ceramic circuit board 100 in this embodiment. As shown in FIG. 1, the ceramic circuit board 100 has a ceramic substrate 10 and a metal circuit layer 20 formed on the ceramic substrate 10. The metal circuit layer 20 has a prescribed circuit pattern and includes Cu, Mg, at least one element (evaporation suppression element for Mg) selected from the group consisting of Sn, Sb, and Bi, and at least one active metal element selected from the group consisting of Ti, Zr, Hf, V, Nb, Ta, Cr, Mo, and W.

For example, the ceramic substrate 10 is a ceramic plate obtained by pressurizing and sintering ceramic granules. Preferably, plates of aluminum nitride (AIN), silicon nitride (Si₃N₄), and alumina (Al₂O₃) can be used for the ceramic substrate 10. The shape and size of the ceramic substrate 10 are not particularly limited.

Conventionally, when a ceramic substrate is formed from an oxide such as alumina (Al), it is necessary to form a layer including molybdenum (Mo) or the like on the surface of the ceramic substrate in advance to ensure adhesion between the ceramic substrate and a metal circuit layer. Meanwhile, in the ceramic circuit board 100 for this aspect, an interfacial reaction layer 21 containing at least one from among a compound of an active metal element and magnesium oxide (MgO) is formed between the ceramic substrate 10 and the metal circuit layer 20; it is therefore possible to ensure adhesion between the ceramic substrate 10 and the metal circuit layer 20 without forming a layer containing Mo or the like in advance. The interfacial reaction layer 21 is described in detail later.

The metal circuit layer 20 has a prescribed circuit pattern, includes Cu and Mg, for example, and further includes at least one active metal element selected from the group consisting of Ti, Zr, Hf, V, Nb, Ta, Cr, Mo, and W. The metal circuit layer 20 may also contain at least one element (evaporation suppression element for Mg) selected from the group consisting of Sn, Sb, and Bi. The metal circuit layer 20 may also contain at least one element (melting point-lowering element) selected from the group consisting of Ag, In, and Mn. In this embodiment, a case where Ti is used as the active metal element is mainly explained.

The metal circuit layer 20 is formed by heat treatment of the brazing material for circuit formation 50 described in (1). The brazing material for circuit formation 50 used in this embodiment is a Cu—Mg based brazing material in which Ag is not the main component. By using this brazing material for circuit formation 50, costs can be reduced compared to using a brazing material containing Ag as the main component. In addition, said brazing material for circuit formation 50 has excellent wettability to the ceramic substrate 10 and improved strength; it is therefore possible to enhance design flexibility in the thickness of the metal circuit layer 20. Furthermore, since the heat treatment temperature when forming the metal circuit layer 20 can be lowered with said brazing material for circuit formation 50, warpage and residual stress caused by differences in thermal expansion coefficients can be reduced. Moreover, the brazing material for circuit formation 50 used in this embodiment may also contain at least one element (melting point-lowering element) selected from the group consisting of Ag, In, and Mn from the viewpoint of further lowering the melting point. However, in terms of electrical conductivity and electromigration, the total content of the melting point-lowering element is preferably 50 at % or less (less than 40 at % for each element alone). The total content of the melting point-lowering element is more preferably 35 at % or less, and even more preferably 20 at % or less.

Since the brazing material for circuit formation 50 contains an evaporation suppression element for Mg as described above, Mg in the brazing material hardly evaporates during heat treatment, and the content thereof does not significantly decrease. In addition, since the brazing material for circuit formation 50 is heat-treated without contacting another metal plate or the like, there is almost no diffusion of metal from the other metal plate or the like into the brazing material, or from the brazing material to the other metal plate or the like. Therefore, it can be said that the content of each element is substantially the same in the metal circuit layer 20 and the brazing material for circuit formation 50. Specifically, in the metal circuit layer 20, it is preferable that Cu has the highest content among the elements contained in the metal circuit layer 20, the content of Cu is preferably 40 to 85 at %, the content of Mg is preferably 1 to 25 at %, the total content of the evaporation suppression element for Mg is preferably 1 to 25 at %, and the total content of the active metal element is preferably 0.1 to 10 at %. In addition, the total content of the melting point-lowering element is preferably 50 at % or less (less than 40 at % for each element alone). The total content of the melting point-lowering element is more preferably 35 at % or less, and even more preferably 20 at % or less. If the evaporation of Mg is suppressed during the period from the start of heat treatment until the entirety of the brazing material for circuit formation 50 is melted, the effect of Mg (suppression of voids, etc.) is exerted. Even if a portion of Mg evaporates and the Mg content in the metal circuit layer 20 decreases to some extent afterwards, there is no problem.

Since the metal circuit layer 20 is formed using the aforementioned brazing material for circuit formation 50, it is possible to increase the bonding strength between the metal circuit layer 20 and the ceramic substrate 10 compared to when using a conductive paste containing conductive particles and glass frit as described in Patent Literature 2, for example. As a result, it is possible to enhance design flexibility in the thickness of the metal circuit layer 20 for enhancing heat dissipation and conductivity.

As shown in FIG. 1, an interfacial reaction layer 21 containing at least one from among a compound of an active metal element and MgO is preferably present between the ceramic substrate 10 and the metal circuit layer 20. The interfacial reaction layer 21 is, for example, a layer formed by the reaction of a portion of the ceramic substrate 10 with an active metal element included in the brazing material for circuit formation 50 and a portion of Mg. In this embodiment in which the brazing material for circuit formation 50 contains Ti as the active metal element, when the ceramic substrate 10 contains a nitride such as AlN or Si₃N₄, the interfacial reaction layer 21 contains titanium nitride (TiN), and when the ceramic substrate 10 contains an oxide such as alumina, the interfacial reaction layer 21 contains MgO. The presence of the interfacial reaction layer 21 improves the adhesion of the metal circuit layer 20. In addition, since heat is easily transferred to the ceramic substrate 10, heat dissipation is also improved.

The interfacial reaction layer 21 may also contain a silicide or aluminide of active metal elements. When the ceramic substrate 10 contains Si₃N₄. the interfacial reactive layer 21 may contain a silicide of active metal elements such as Ti₅Si₃, and when the ceramic substrate 10 contains AlN, the interfacial reactive layer 21 may contain aluminides of active metal elements such as TiAl.

As shown in FIG. 1, the metal circuit layer 20 preferably includes a solid solution phase 22 in which another metal element is dissolved in Cu as a solid solution, and a compound phase 23 having at least one intermetallic compound selected from the group consisting of Cu₄MgSn, CuMgSb, and CuMgBi.

For example, the solid solution phase 22 contains, as the main component, a solid solution in which Mg or the like is dissolved in a Cu crystal. In some cases, another metal element or an active metal element contained in the brazing material for circuit formation 50 may be dissolved in the crystal as a solid solution. As a result of another metal element being dissolved in Cu, the strength of the solid solution phase 22 (the strength of the metal circuit layer 20) can be improved through solid solution reinforcement.

As for the amount of each metal element dissolved in Cu in the solid solution phase 22, the amount of dissolved Mg is preferably 5 at % or less, the amount of dissolved Sn is preferably 5 at % or less, the amount of dissolved Sb is preferably 4 at % or less, and the amount of dissolved Bi is preferably 1 at % or less, for example. The amount of each dissolved metal element can be measured by, for example, energy dispersive X-ray analysis (EDX).

When Mg and Sn are dissolved in Cu in the solid solution phase 22, provided that the amount of dissolved Mg is A and the amount of dissolved Sn is B, the ratio A/B is preferably 0.1 or more and 2.0 or less. As a result of Mg and Sn being dissolved in Cu in such a ratio, the strength of the metal circuit layer 20 can be further increased.

The compound phase 23 is formed by precipitation of at least one intermetallic compound selected from Cu₄MgSn, CuMgSb, and CuMgBi, for example. The compound phase 23 may include another intermetallic compound formed from Cu, Mg, an evaporation suppression element for Mg, a melting point-lowering element, and an active metal element. As a result of a trace amount of the compound phase 23 being present in the metal circuit layer 20, the strength of the metal circuit layer 20 can be improved through precipitation reinforcement. From this point of view, it is preferable that the compound phase 23 is uniformly dispersed in the solid solution phase 22. In addition, as a result of an appropriate amount of the compound phase 23 being present, the amount of another dissolved metal element in Cu in the solid solution phase 22 is reduced, thereby improving the thermal conductivity.

The thickness of the metal circuit layer 20 can be, for example, 5 μm or more. The metal circuit layer 20 is formed using the aforementioned brazing material for circuit formation 50 and thus has excellent wettability to the ceramic substrate 10 and increased bonding strength; it is therefore possible to make the metal circuit layer 20 thicker. In other words, it is possible to enhance design flexibility in the thickness of the metal circuit layer 20. By making the metal circuit layer 20 thicker, heat dissipation is improved, making it suitable for applications where high current flows. Although the upper limit of the thickness of the metal circuit layer 20 is not particularly limited, the upper limit may be set to 300 μm or less, for example, from the viewpoint of preventing the cost from being too high. The thickness of the metal circuit layer 20 is preferably 20 to 150 μm and preferably 50 to 100 μm. The thickness of the metal circuit layer 20 may be measured, for example, by observing the cross-sectional structure with a SEM, measuring three points, and taking the average value of said points.

Forming the metal circuit layer 20 using the aforementioned brazing material for circuit formation 50 suppresses generation of voids. When a brazing material for circuit formation containing Mg is used, there is concern that voids and pinholes (hereinafter collectively referred to as voids) may occur in the metal circuit layer due to the evaporation of Mg contained in the brazing material for circuit formation. The presence of such voids is a factor that reduces the strength of the metal circuit layer 20. In this embodiment, as a result of including at least one element selected from Sn, Sb, and Bi, which are elements that suppress evaporation of Mg, in the brazing material for circuit formation 50, it is possible to suppress evaporation of Mg and generation of voids in the metal circuit layer 20.

Specifically, the metal circuit layer 20 for this embodiment has an extremely excellent feature in that, when the cross section thereof is observed, not a single void with an equivalent circle diameter of 8 μm or more is observed within any field of view of approximately 10,000 μm². In other words, when the cross section of the metal circuit layer 20 is observed, the number of voids with an equivalent circle diameter of 8 μm or more is preferably no more than 1 per 10,000 μm², the number of voids with an equivalent circle diameter of 4 μm or more is preferably no more than 1 per 10,000 μm², and the number of voids with an equivalent circle diameter of 1 μm or more is preferably no more than 1 per 10,000 μm².

In this embodiment, as a result of the metal circuit layer 20 being formed by the aforementioned brazing material for circuit formation 50, the bonding strength between the metal circuit layer 20 and the ceramic substrate 10 is high. Specifically, the shear strength of the metal circuit layer 20 in this embodiment is 20 MPa or more. In addition, the tensile strength of the metal circuit layer 20 in this embodiment is 40 MPa or more.

The shear strength of the metal circuit layer 20 refers to the amount of shear load per unit area required to fracture (shear fracture) the metal circuit layer 20 when stress (shear stress) is applied to the metal circuit layer 20 so that the metal circuit layer 20 and the ceramic substrate 10 are shifted along the opposite directions parallel to the bonding surface. In addition, the tensile strength of the metal circuit layer 20 refers to the amount of tensile load per unit area required to fracture the metal circuit layer 20 when stress (tensile stress) is applied to the metal circuit layer 20 so that the metal circuit layer 20 and the ceramic substrate 10 are pulled apart along the direction perpendicular to the bonding surface.

### (3) Manufacturing Method for Ceramic Circuit Board

Next, the method for manufacturing the ceramic circuit board 100 is described.

As shown in FIG. 2, a brazing material for circuit formation 50 for forming a metal circuit layer 20 is placed on a ceramic substrate 10 so as to correspond to a prescribed circuit pattern. The brazing material for circuit formation 50 is described in (1) and (2), so the description therefor is omitted. As the method for placing the brazing material for circuit formation 50, known methods such as screen printing, transfer printing, dispensing, inkjet printing, spray coating, sputtering, and vapor deposition can be used.

In this embodiment, even when the ceramic substrate 10 is formed from an oxide such as alumina, it is possible to apply the brazing material for circuit formation 50 thereon without forming a layer including Mo or the like on the surface of the ceramic substrate 10 in advance.

Once the brazing material for circuit formation 50 has been placed, the ceramic substrate 10 and the brazing material for circuit formation 50 are heated and held in a prescribed atmosphere. In this manner, the brazing material for circuit formation 50 is bonded onto the ceramic substrate 10 to form the metal circuit layer 20. The prescribed atmosphere can be either a vacuum atmosphere (reduced pressure atmosphere), an inert gas atmosphere, or a reduction atmosphere. It is possible to adjust the oxygen concentration by introducing an inert gas such as nitrogen (N₂). It is possible to reduce copper oxide and suppress oxidation of brazing material components such as Cu and Mg by introducing a reducing gas such as hydrogen (H₂).

The heat treatment temperature is preferably set to 600° C. or more and 950° C. or less, more preferably 720° C. or more and 900° C. or less, and even more preferably 740° C. or more and 850° C. or less, for example. By keeping the heat treatment temperature below 950° C., warpage and residual stress caused by differences in thermal expansion coefficients can be reduced. In addition, setting the heat treatment temperature to 600° C. or more improves diffusivity of the active metal elements and facilitates the formation of the interfacial reaction layer 21. For the heat treatment furnace used for bonding, a known furnace such as a static batch furnace, a multi-chamber furnace, a belt conveyor furnace, or a roller hearth kiln can be used.

Other conditions for bonding are shown below.

Oxygen concentration: 0.01 ppm or more and 1000 ppm or less (preferably 0.01 ppm or more and 100 ppm or less, more preferably 0.01 ppm or more and 10 ppm or less)
Retention time: there are no particular restrictions, but 30 minutes or more and 180 minutes or less, for example

After heat treatment, the ceramic substrate 10 is cooled down. With the aforementioned processes, it is possible to manufacture the ceramic circuit board 100 for this embodiment.

### Other Embodiments of this Disclosure

The embodiment of this disclosure has been explained in detail. However, the disclosure is not limited to the aforementioned embodiment and various modifications can be made without departing from the gist thereof.

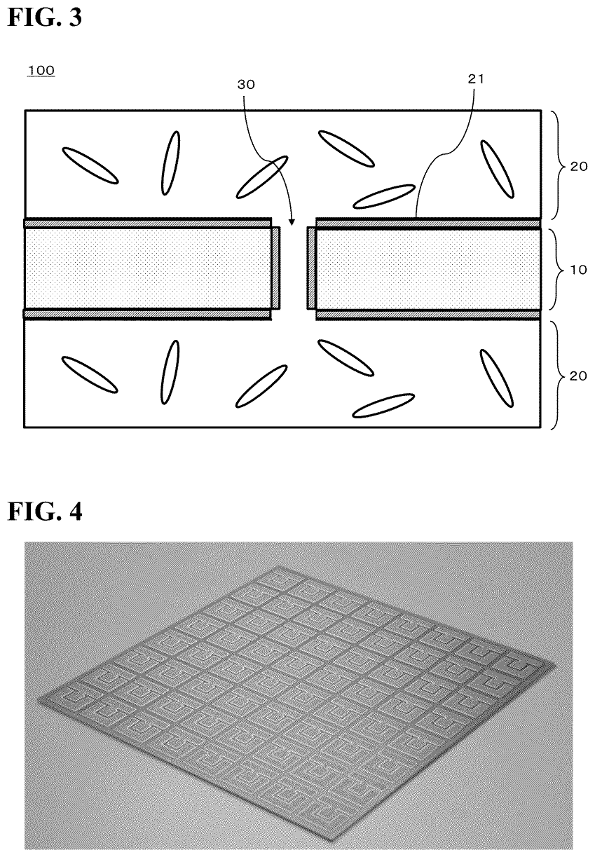

For example, in the aforementioned embodiment, a case where the metal circuit layer 20 is formed only on one of the main surfaces (that is, one surface) of the ceramic substrate 10 is explained. However, as shown in FIG. 3, the metal circuit layer 20 can be formed on both the main surfaces (that is, both surfaces) of the ceramic substrate 10. In this case, a through-hole 30 (also called via) may be formed in the ceramic substrate 10, and the brazing material for circuit formation 50 may also be filled in the through-hole 30, so that the metal similar to the metal forming the metal circuit layer 20 is filled in the through-hole 30. As a result, the metal circuit layer 20 on the front surface and the metal circuit layer 20 on the rear surface are electrically connected, making it possible to achieve a ceramic circuit board 100 having a more complex circuit pattern. The metal similar to the metal forming the metal circuit layer 20 mentioned here is the metal that is formed in the same manner as the metal forming the metal circuit layer. In addition, the brazing material for circuit formation 50 has high wettability to the ceramic substrate 10, so it is easy to fill the through-hole 30 with the brazing material for circuit formation 50. Moreover, because the interfacial reaction layer 21 is also formed around the through-hole 30, adhesion and strength are improved, and a ceramic circuit board 100 having enhanced design flexibility in the thickness of the metal circuit layer 20 can be achieved.

### Examples

### (Preparation of Samples 1-5)

As the ceramic substrate 10, an alumina plate of 10 mm×10 mm×0.32 mm and an aluminum nitride plate of 10 mm×10 mm×0.65 mm were prepared. As the brazing material for circuit formation 50, pastes obtained by mixing the metal elements in the ratios shown in Table 1 were used. For pasting, terpineol was used as a solvent and polyisobutyl methacrylate was used as a binder. The total amount of the solvent and binder in the paste was 17 mass %. The pastes were applied to the ceramic substrates 10 so as to correspond to a prescribed circuit pattern shape using screen printing method. After that, heat treatment for 120 minutes at the prescribed heat treatment temperature and atmosphere as shown in Table 1 is performed to prepare samples 1 and 2.

TABLE 1

| | | | | | | | | | | | Evaluation | |
|---|---|---|---|---|---|---|---|---|---|---|---|---|
| | | | | | | | | | | | Bonding | Interfacial |
| | Brazing material composition [at %] | | | | | | | Ceramic | Heat treatment condition | | strength | reaction |
| | Cu | Mg | Sn | Sb | Bi | Ag | Ti | substrate | Temperature | Atmosphere | [MPa] | layer |
| Sample 1 | 62.9 | 16.4 | 16.7 | — | — | — | 4.0 | Si₃N₄ | 800° C. | Vacuum | 124.2 | ◯ |
| Sample 2 | 76.2 | 10.5 | — | 9.7 | — | — | 3.6 | Si₃N₄ | 800° C. | Vacuum | 139.5 | ◯ |
| Sample 3 | 76.3 | 9.7 | 9.1 | — | 0.9 | — | 4.0 | Si₃N₄ | 800° C. | Vacuum | 142.7 | ◯ |
| Sample 4 | 77.0 | 7.1 | 5.8 | — | — | 6.1 | 4.0 | Al₂O₃ | 800° C. | Vacuum | 93.2 | ◯ |
| Sample 5 | 77.0 | 7.1 | 5.8 | — | — | 6.1 | 4.0 | AlN | 800° C. | Vacuum | 95.0 | ◯ |

### (Cross-Sectional Tissue Evaluation)

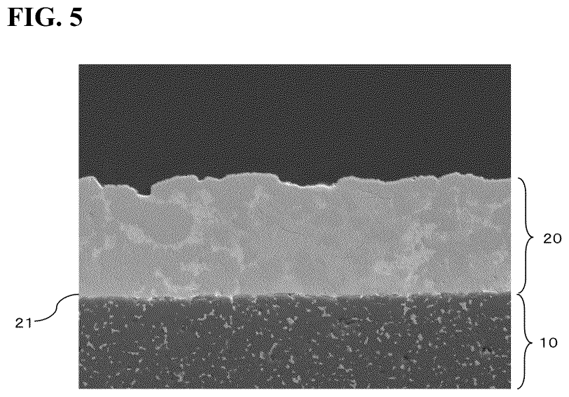

Cross-sectional tissue was SEM observed for samples 1 to 5. FIG. 4 shows an external image of sample 5, and FIG. 5 shows a cross-sectional SEM image of sample 5. As shown in FIG. 5, the metal circuit layer 20 was formed on the ceramic substrate 10, and it was confirmed that there were no noticeable voids with an equivalent circle diameter of 20 um or more in the metal circuit layer 20. It was also confirmed that the interfacial reaction layer 21 containing an active metal element (Ti in this case) existed between the ceramic substrate 10 and the metal circuit layer 20. In sample 1, the interfacial reaction layer 21 containing MgO was present. Samples in which the interfacial reactive layer 21 was confirmed between the ceramic substrate 10 and the metal circuit layer 20 were indicated with “O” in the interfacial reactive layer column in Table 1.

### (Evaluation of Bonding Strength)

For samples 1 to 5, the bonding strength of the metal circuit layer 20 was evaluated by a shear strength test. Specifically, a test piece was prepared by processing the metal circuit layer 20 into a cylindrical shape with a diameter of 3 mm, and exposing the bonding surface of the surrounding ceramic material. Then, with the ceramic substrate 10 of the test piece fixed, the cylindrical metal circuit layer 20 was pressed using a displacement jig along a direction parallel to the bonding surface, and the magnitude of stress at which the metal circuit layer 20 was fractured (shear fractured) was measured. Based on this value, the shear strength of the bonding layer was calculated. The shear test position (contact height H of the displacement jig) was set at a height of 200 μm from the exposed surface of the ceramic material, and the movement speed of the displacement axis was set at 100 μm/s. The results are shown in Table 1.

As shown in Table 1, the bonding strengths of samples 1 to 5 (shear strengths of the metal circuit layers 20) were all 20 MPa or more, and it was confirmed that the samples had high bonding strengths.

It was confirmed from the above that by using the aforementioned brazing material for circuit formation 50, it is possible to manufacture a ceramic circuit board 100 at a lower cost than when a brazing material containing Ag as the main component is used. In addition, it was confirmed that the ceramic circuit board 100 has high bonding strength and offers enhanced design flexibility in the thickness of the metal circuit layer 20.

<Preferred Aspect of this Disclosure>

The preferred aspect of this disclosure is described below.

According to one aspect of this disclosure, provided is
a ceramic circuit board comprising
   a ceramic substrate, and
a metal circuit layer formed on the ceramic substrate, wherein
the metal circuit layer contains
Cu,
Mg,
at least one element selected from the group consisting of Sn, Sb, and Bi, and
at least one active metal element selected from the group consisting of Ti, Zr, Hf, V, Nb, Ta, Cr, Mo, and W.

Preferably,
Cu is the element having the highest content among the elements contained in the metal circuit layer. The content is based on at %.

Preferably,

in the metal circuit layer, the Cu content is 40 to 85 at %, the Mg content is 0.2 to 25at %, and the total content of Sn, Sb, and Bi is 1 to 25 at %.

Preferably,
an interfacial reaction layer containing at least one from among a compound of the active metal element and MgO is present between the ceramic substrate and the metal circuit layer.

Preferably,
the metal circuit layer further contains at least one element selected from the group consisting of Ag, In, and Mn.

Preferably,
the metal circuit layer includes: a solid solution phase in which a metal element other than Cu is dissolved in Cu; and a compound phase having at least one intermetallic compound selected from the group consisting of Cu₄MgSn, CuMgSb, and CuMgBi.

Preferably,
the thickness of the metal circuit layer is 5 μm or more and 300 μm or less.

Preferably,
when the cross section of the metal circuit layer is observed, the number of voids with an equivalent circle diameter of 8 μm or more is preferably no more than 1 per 10,000 μm².

Preferably,
the ceramic substrate has a through-hole, and
a metal similar to the metal forming the metal circuit layer is filled in the through-hole.

According to another aspect of this disclosure, provided is
a method for manufacturing a ceramic circuit board, the method comprising:
   placing a brazing material for circuit formation on a ceramic substrate in such a manner that the brazing material for circuit formation corresponds to a circuit pattern, the brazing material for circuit formation containing
Cu,
Mg,
   at least one first element selected from the group consisting of Sn, Sb, and Bi, and
at least one active metal element selected from the group consisting of Ti, Zr, Hf, V, Nb, Ta, Cr, Mo, and W; and
heating and holding the ceramic substrate on which the brazing material for circuit formation has been placed.

Preferably,
Cu is the element having the highest content among the elements contained in the brazing material for circuit formation.

Preferably,
in the step of placing the brazing material for circuit formation, the brazing material for circuit formation contains 40 to 85 at % of Cu, 1 to 25 at % of Mg, a total of 1 to 25 at % of the first element, and a total of 0.1 to 10 at % of the active metal element.

Preferably,
in the step of placing the brazing material for circuit formation, the brazing material for circuit formation further contains a second element being at least one selected from the group consisting of Ag, In, and Mn.

Preferably,
in the step of placing the brazing material for circuit formation,
   provided that the content of Mg is X at % and the content of the first element is Y at %,
   the brazing material for circuit formation satisfies a relationship X−5≤Y≤X+5.

Preferably,
in the step of placing the brazing material for circuit formation, the brazing material for circuit formation is configured as a paste and contains Cu powder including Cu, and alloy powder formed from an intermetallic compound containing at least Mg, the first element, and the active metal element.

Preferably,
in the step of placing of the brazing material for circuit formation, the brazing material for circuit formation is such that the content of Mg derived from the alloy powder is 40% or more of the total Mg content in the brazing material for circuit formation.

Preferably,
in the step of heating and holding of the ceramic substrate, the heating is performed at a temperature of 600° C. or more and 950° C. or less.

According to another aspect of this disclosure, provided is
a brazing material for circuit formation comprising:
Cu;
Mg;
at least one first element selected from the group consisting of Sn, Sb, and Bi; and
at least one active metal element selected from the group consisting of Ti, Zr, Hf, V, Nb, Ta, Cr, Mo, and W.

Preferably,
Cu is the element having the highest content among the elements contained in the brazing material for circuit formation.

Preferably,
the brazing material for circuit formation contains 40 to 85 at % of Cu, 1 to 25 at % of Mg, a total of 1 to 25 at % of the first element, and a total of 0.1 to 10 at % of the active metal element.

Preferably,
the brazing material for circuit formation further contains a second element being at least one selected from the group consisting of Ag, In, and Mn.

### REFERENCE SIGNS LIST

10 Ceramic substrate
20 Metal circuit layer
21 Interfacial reaction layer
22 Solid solution phase
23 Compound phase
30 Through-hole
50 Brazing material for circuit formation
100 Ceramic circuit board

1. A ceramic circuit board comprising:
a ceramic substrate; and
a metal circuit layer formed on the ceramic substrate, wherein
the metal circuit layer contains
Cu,
Mg,
at least one element selected from the group consisting of Sn, Sb, and Bi, and
at least one active metal element selected from the group consisting of Ti, Zr, Hf, V, Nb, Ta, Cr, Mo, and W.

2. The ceramic circuit board according to claim 1, wherein Cu is the element having the highest content among the elements contained in the metal circuit layer.

3. The ceramic circuit board according to claim 1, wherein in the metal circuit layer, the Cu content is 40 to 85 at %, the Mg content is 0.2 to 25 at %, and the total content of Sn, Sb, and Bi is 1 to 25 at %.

4. The ceramic circuit board according to claim 1, wherein an interfacial reaction layer containing at least one from among a compound of the active metal element and MgO is present between the ceramic substrate and the metal circuit layer.

5. The ceramic circuit board according to claim 1, wherein the metal circuit layer further contains at least one element selected from the group consisting of Ag, In, and Mn.

6. The ceramic circuit board according to claim 1, wherein the metal circuit layer includes: a solid solution phase in which a metal element other than Cu is dissolved in Cu; and a compound phase having at least one intermetallic compound selected from the group consisting of Cu₄MgSn, CuMgSb, and CuMgBi.

7. The ceramic circuit board according to claim 1, wherein the thickness of the metal circuit layer is 5 μm or more and 300 μm or less.

8. The ceramic circuit board according to claim 1, wherein
the ceramic substrate has a through-hole, and
a metal similar to the metal forming the metal circuit layer is filled in the through-hole.

9. A method for manufacturing a ceramic circuit board, the method comprising:
placing a brazing material for circuit formation on a ceramic substrate in such a manner that the brazing material for circuit formation corresponds to a circuit pattern, the brazing material for circuit formation containing
Cu
Mg,
at least one first element selected from the group consisting of Sn, Sb, and Bi, and
at least one active metal element selected from the group consisting of Ti, Zr, Hf, V, Nb, Ta, Cr, Mo, and W; and
heating and holding the ceramic substrate on which the brazing material for circuit formation has been placed.

10. The method for manufacturing a ceramic circuit board according to claim 9, wherein Cu is the element having the highest content among the elements contained in the brazing material for circuit formation.

11. The method for manufacturing a ceramic circuit board according to claim 9, wherein in the step of placing the brazing material for circuit formation, the brazing material for circuit formation contains 40 to 85 at % of Cu, 1 to 25 at % of Mg, a total of 1 to 25 at % of the first element, and a total of 0.1 to 10 at % of the active metal element.

12. The method for manufacturing a ceramic circuit board according to claim 11, wherein in the step of placing the brazing material for circuit formation, the brazing material for circuit formation further contains a second element being at least one selected from the group consisting of Ag, In, and Mn.

13. The method for manufacturing a ceramic circuit board according to claim 9, wherein
in the step of placing the brazing material for circuit formation,
provided that the content of Mg is X at % and the content of the first element is Y at %, the brazing material for circuit formation satisfies a relationship X−5≤Y≤X+5.

14. The method for manufacturing a ceramic circuit board according to claim 9, wherein in the step of placing the brazing material for circuit formation, the brazing material for circuit formation is configured as a paste and contains Cu powder including Cu, and alloy powder formed from an intermetallic compound containing at least Mg, the first element, and the active metal element.

15. The method for manufacturing a ceramic circuit board according to claim 9, wherein
in the step of heating and holding of the ceramic substrate, the heating is performed at a temperature of 600° C. or more and 950° C. or less.

16. A brazing material for circuit formation comprising:
Cu;
Mg;
at least one first element selected from the group consisting of Sn, Sb, and Bi; and
at least one active metal element selected from the group consisting of Ti, Zr, Hf, V, Nb, Ta, Cr, Mo, and W.

17. The brazing material for circuit formation according to claim 16, wherein Cu is the element having the highest content among the elements contained in the brazing material for circuit formation.

18. The brazing material for circuit formation according to claim 16, wherein the brazing material for circuit formation contains 40 to 85 at % of Cu, 1 to 25 at % of Mg, a total of 1 to 25 at % of the first element, and a total of 0.1 to 10 at % of the active metal element.

19. The brazing material for circuit formation according to claim 18, wherein the brazing material for circuit formation further contains a second element being at least one selected from the group consisting of Ag, In, and Mn.
